(19) United States
(12) Patent Application Publication
(10) Pub. No.: US 2010/0051101 A1
(43) Pub. Date: Mar. 4, 2010

(54) Electrode of flexible dye-sensitized solar cell, manufacturing method thereof and flexible dye-sensitized solar cell

(75) Inventors: Hyun-Jun Kim, Suwon-si (KR); Sung-Soo Park, Seongnam-si (KR); Soo-Young Ji, Suwon-si (KR); Young-Sun Won, Seoul (KR)

Correspondence Address: STAAS & HALSEY LLP, SUITE 700, 1201 NEW YORK AVENUE, N.W., WASHINGTON, DC, 20005, US

(73) Assignee: SAMSUNG ELECTRO-MECHANICS CO., LTD., Suwon (KR)

(21) Appl. No.: 12/585,007

(22) Filed: Aug. 31, 2009

(30) Foreign Application Priority Data
Sep. 1, 2008 (KR) 10-2008-0086018

(51) Int. Cl. H01L 31/0216; H01L 31/18

(52) U.S. Cl. 136/256; 438/69; 257/E21.211; 257/E31.119

(57) ABSTRACT

A flexible dye-sensitized solar cell, an electrode of a flexible dye-sensitized solar cell and a method of manufacturing the flexible dye-sensitized solar cell are disclosed. The method of manufacturing the flexible dye-sensitized solar cell in accordance with an embodiment of the present invention includes: forming a separation layer on a carrier; forming a dye-absorption layer on the separation layer; forming a carbon-nanotube layer on the dye-absorption layer; forming a cathode polymer layer on the carbon-nanotube layer, in which the cathode polymer layer is flexible; and separating the carrier by removing the separation layer. Although the high temperature annealing process associated with the dye-sensitized solar cell is required, a flexible cathode transparent electrode can be manufactured by using the carbon nanotube, because the cathode can be manufactured by using the carbon nanotube and a flexible transparent board is used.

### CROSS-REFERENCE TO RELATED APPLICATIONS

This application claims the benefit of Korean Patent Application No. 10-2008-0086018, filed with the Korean Intellectual Property Office on Sep. 1, 2008, the disclosure of which is incorporated herein by reference in its entirety.

### BACKGROUND

1. Technical Field

The present invention relates to a flexible dye-sensitized solar cell, an electrode of a flexible dye-sensitized solar cell and a method of manufacturing the flexible dye-sensitized solar cell.

2. Description of the Related Art

A solar cell is a solar conversion electronic device that converts sunlight into electrical energy and, unlike other energy sources, is infinite and environmentally friendly, thereby increasingly gaining its importance. While a single crystalline or polycrystalline silicon solar cell was often used in the past, alternative approaches have been sought because of the high production cost and limited improvement in solar conversion efficiency of the conventional solar cell. As an alternative to the silicon solar cell, a dye-sensitized solar cell is extremely promising because it is made of low-cost materials, for example, organic materials, lowering the production cost.

The dye-sensitized solar cell is a relatively new class of low cost solar cell that chemically generates electricity using its ability to create a conduction electron when a dye absorbs sunlight. Because of its advantages, such as low-cost materials, easy production, flexibility, light weight and transparency, the dye-sensitized solar cell can be used in many applications, including a self-recharging power source that is needed for the next generation PC, e.g., a wearable PC, or a power source that is affixed to clothes, hats, mobile phones, automotive glasses and buildings. As a result, the dye-sensitized solar cell is emerging as one of the next generation solar cell technologies that can replace the silicon solar cell market in the future.

Generally, the dye-sensitized solar cell has two primary parts: a lower electrode and a corresponding electrode. On the top is a transparent electrode made of indium tin oxide (ITO) deposited on the back of a glass board. On the back of the glass board is a thin layer of the indium tin oxide (ITO), and then a dye absorption layer having a dye absorbed therein is adhered to a surface of the indium tin oxide (ITO). The corresponding electrode is made with a thin layer of an electrolyte spread over a conductive sheet. The absorption layer is made of n-type oxide semiconductors having a wide range of energy differences, and a monomolecular layer of a dye is adhered to a surface of the absorption layer.

The lower electrode of a majority of traditional dye-sensitized solar cells is made with a TiO₂ layer, and a dye layer is adhered to the surface of the TiO₂ layer to capture solar energy. In order to form the TiO₂ layer, an annealing process of high temperatures, about 450° C., is required, and thus a flexible board, such as a sheet of plastic, and a flexible transparent electrode, such as a conductive polymer, cannot be used as a cathode.

Low temperature annealing paste can be printed on a flexible board and then dried at a low temperature of 100° C. or lower, or a dye absorption layer can be formed on the top of an opaque metal foil film. However, there have been difficulties due to a variety of problems, for example, low-efficiency in solar conversion and a reliability issue on films.

### SUMMARY

The present invention provides a flexible dye-sensitized solar cell, an electrode of a flexible dye-sensitized solar cell, in which a carbon nanotube is used as a cathode, and a method of manufacturing the flexible dye-sensitized solar cell.

An aspect of the present invention provides a method of manufacturing a flexible dye-sensitized solar cell. The method of manufacturing the flexible dye-sensitized solar cell in accordance with an embodiment of the present invention includes: forming a separation layer on a carrier; forming a dye-absorption layer on the separation layer; forming a carbon-nanotube layer on the dye-absorption layer; forming a cathode polymer layer on the carbon-nanotube layer, in which the cathode polymer layer is flexible; and separating the carrier by removing the separation layer.

The carrier can be selected from a group consisting of glass, metal and silicone, and the separation layer can include ZnO nanowire (is a nanowire that includes ZnO). Here, the separating of the carrier can include removing the separation layer by sonicating ZnO in a subacidic environment.

The forming of the dye-absorption layer can include: coating nano-crystal oxide; and annealing the nano-crystal oxide. Here, the nano-crystal oxide can include TiO₂, ZnO, Nb₂O₅, WO₃, SnO₂ and MgO.

The cathode polymer layer can be made of a material including at least one selected from a group consisting of polyethylene terephthalate (PET), polyethylene naphathalate (PEN), polyimides, polymeric hydrocarons, celluloses, plastic, polycarbonate and polystyrene. Here, the method can further include absorbing photosensitive dye into the dye-absorption layer.

Another aspect of the present invention provides an electrode of a flexible dye-sensitized solar cell. The electrode in accordance with an embodiment of the present invention includes: a cathode polymer layer, which is flexible; a carbon-nanotube layer formed on one side of the cathode polymer layer; and a dye-absorption layer formed on the carbon-nanotube layer.

The cathode polymer layer can be made of a material including at least one selected from a group consisting of polyethylene terephthalate (PET), polyethylene naphathalate (PEN), polyimides, polymeric hydrocarons, celluloses, plastic, polycarbonate and polystyrene. The dye-absorption layer can be made of a material including one or more selected from a group consisting of TiO₂, ZnO, Nb₂O₅, WO₃, SnO₂ and MgO.

Photosensitive dye can be absorbed into the dye-absorption layer.

Another aspect of the present invention provides a flexible dye-sensitized solar cell. The flexible dye-sensitized solar cell in accordance with an embodiment of the present invention includes: a cathode, which includes: a cathode polymer layer, which is flexible, a carbon-nanotube layer formed on one surface of the cathode polymer layer, and a dye-absorption layer formed on the carbon-nanotube layer; an anode, in which a conductive substance layer is formed on the anode; and an electrolyte, which is interposed between the cathode and the anode.

The cathode polymer layer can be made of a material including at least one selected from a group consisting of polyethylene terephthalate (PET), polyethylene naphathalate (PEN), polyimides, polymeric hydrocarons, celluloses, plastic, polycarbonate and polystyrene. The dye-absorption layer can be made of a material including one or more selected from a group consisting of TiO₂, ZnO, Nb₂O₅, WO₃, SnO₂ and MgO.

Photosensitive dye can be absorbed into the dye-absorption layer.

Additional aspects and advantages of the present invention will be set forth in part in the description which follows, and in part will be obvious from the description, or may be learned by practice of the invention.

### BRIEF DESCRIPTION OF THE DRAWINGS

FIG. 1 is a flowchart illustrating a method of manufacturing a flexible dye-sensitized solar cell in accordance with an embodiment of the present invention.

FIGS. 2 to 7 are flow diagrams illustrating a method of manufacturing a flexible dye-sensitized solar cell in accordance with an embodiment of the present invention.

FIG. 8 is a cross sectional view illustrating a flexible dye-sensitized solar cell in accordance with another embodiment of the present invention.

### DETAILED DESCRIPTION

As the invention allows for various changes and numerous embodiments, particular embodiments will be illustrated in the drawings and described in detail in the written description. However, this is not intended to limit the present invention to particular modes of practice, and it is to be appreciated that all changes, equivalents, and substitutes that do not depart from the spirit and technical scope of the present invention are encompassed in the present invention. In the description of the present invention, certain detailed explanations of related art are omitted when it is deemed that they may unnecessarily obscure the essence of the invention.

The terms used in the present specification are merely used to describe particular embodiments, and are not intended to limit the present invention. An expression used in the singular encompasses the expression of the plural, unless it has a clearly different meaning in the context. In the present specification, it is to be understood that the terms such as “including” or “having,” etc., are intended to indicate the existence of the features, numbers, steps, actions, components, parts, or combinations thereof disclosed in the specification, and are not intended to preclude the possibility that one or more other features, numbers, steps, actions, components, parts, or combinations thereof may exist or may be added.

A flexible dye-sensitized solar cell in accordance with certain embodiments of the present invention will be described below in more detail with reference to the accompanying drawings. Those components that are the same or are in correspondence are rendered the same reference numeral regardless of the figure number, and redundant explanations are omitted.

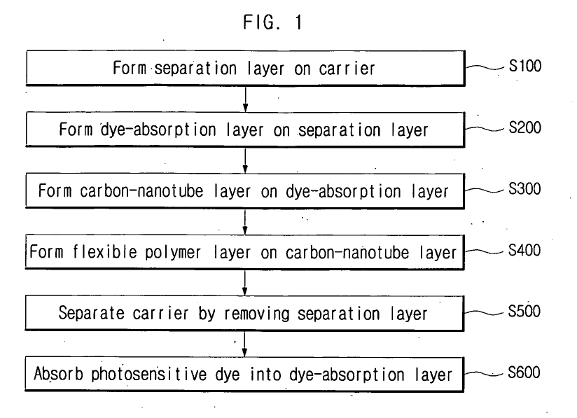

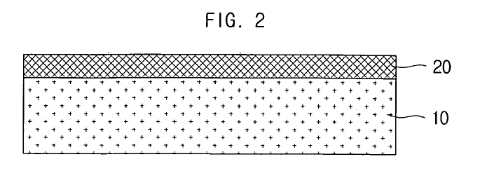

FIG. 1 is a flowchart illustrating a method of manufacturing a flexible dye-sensitized solar cell in accordance with an embodiment of the present invention, and FIGS. 2 to 7 are flow diagrams illustrating a method of manufacturing the flexible dye-sensitized solar cell in accordance with an embodiment of the present invention. Illustrated in FIGS. 2 to 7 are a carrier 10, a separation layer 20, a dye-absorption layer 30, a carbon-nanotube layer 40 and a cathode polymer layer 50.

First of all, as illustrated in FIG. 2, the separation layer 20 is formed on the carrier 10 (S100). The carrier 10 is a material that is removed after forming an electrode, and it is usually made of glass, metal, having a high melting point, and silicone. Nevertheless, any types of materials, which can bear the heat being supplied when annealing a dye-absorption layer 30, can be used for the carrier 10.

The separation layer 20 includes a substance, for example, ZnO nanowire, that can be removed without giving any effect to the finished electrode such that the carrier 10 can be easily separated after making the electrode. ZnO can be dissolved by sonicating in a subacidic environment and thus easily removed.

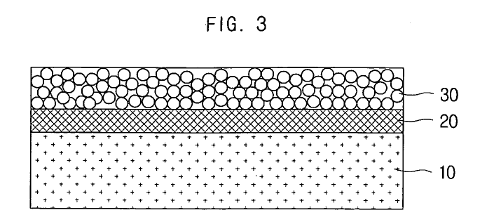

Next, as illustrated in FIG. 3, the dye-absorption layer 30 is formed on the separation layer 20 (S200). The dye-absorption layer 30, absorbing photosensitive dye therein, absorbs solar energy and converts it into electric energy by activating electrons.

As such, the dye-absorption layer 30 is formed by using nano-crystal oxide. The nano-crystal oxide is a substance that can adhere photosensitive dye to a surface thereof and thus provide a superior solar cell electrode because it provides an enough surface to which the dye can be adhered.

As the nano-crystal oxide, TiO₂ is more commonly used. TiO₂ occurs in nature as the well-known naturally occurring minerals anatase, rutile and brookite. Anatase, one of the three mineral forms of TiO₂, is always found as small (nanometer sized) crystals and can be manufactured through the Hydrothermal Epitaxy method. Rutile, a mineral composed primarily of TiO₂, is stable in a low temperature environment and can be thus manufactured in a normal temperature environment through the Hydrolytic method. Rutile has a tetragonal unit cell, which is a rectangular prism with a diameter of 20 nm and a length of 80 nm, but Anatase has a spherical shape unit cell with a diameter of 20 nm, so that Anatase generates more photoelectric currents due to its wider surface area.

In order to form the dye-absorption layer 30 consisting of the anatase form of TiO₂, TiO₂ is coated and then treated through an annealing process in a high-temperature environment, about 450 degrees Celsius. However, during the annealing process, the heat of about 450 degrees Celsius may be applied to an electrode, the dye-absorption layer 30 cannot be thus formed on a general soft polymer and carbon nanotube due to their low melting points to high temperatures. On the other hand, in accordance with the present embodiment, the dye-absorption layer 30 can be formed before forming a carbon-nanotube layer and a cathode polymer layer 50, and thus the problem of the heat required during the annealing process cannot occur.

Besides the one described above, ZnO, Nb₂O₅, WO₃, SnO₂ and MgO, which closely resemble the structure of TiO₂, can be used as oxide.

The processes of coating and annealing the nano-crystal oxide can be repeated until the required thickness of the dye-absorption layer 30 is achieved.

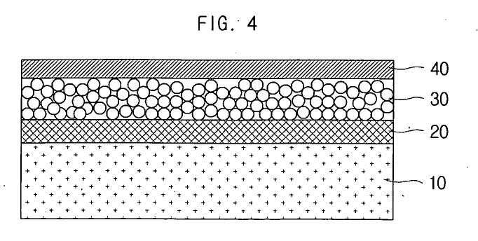

Next, as illustrated in FIG. 4, a carbon-nanotube layer 40 is formed on the dye-absorption layer 30 (S300). The carbon-nanotube layer 40, collecting electrons excited from the dye-absorption layer 30, can include a conductive material. In this embodiment, the carbon-nanotube layer 40 is a conductive polymer filled with carbon-nanotubes. A carbon-nanotubes (CNT) is basically a long hollow cylinder of graphite sheets with a nanostructure in which 6 carbon atoms are arranged in a hexagonal lattice. A diameter of the long hollow cylinder is typically in a range of a few nanometers to a few ten nanometers, and the electrical conductivity of carbon-nanotubes is similar to that of copper. The carbon-nanotube is the greatest material, like a diamond, on earth in terms of thermal conductivity, and its strength is 100 times greater than a metal such as steel. A carbon fiber breaks when only 1% of its components deforms, but the carbon-nanotube can undergo a deformation up to a limit where 15% of its components deforms. As a result, the carbon-nanotube is being spotlighted as the next generation new material. As described above, if the carbon-nanotube layer 40 is formed by a conductive polymer consisting of carbon-nanotubes, even if a carbon-nanotube content ratio is less than 1%, the required electric conductivity can be achieved, so that an electrode of a flexible dye-sensitized solar cell, in which the electrode has transparency and mechanical strength, can be produced.

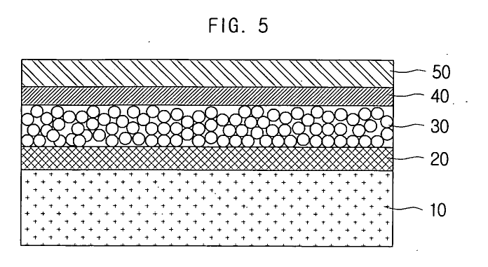

Next, as illustrated in FIG. 5, the cathode polymer layer 50 is formed on the carbon-nanotube layer 40 (S400). In order to implement a flexible dye-sensitized solar cell, a material, which sustains its form without breaking when repeatedly folded, can be used, and a material, which is transparent so that a ray of light shins through it, is required. Here, polyethylene terephthalate (PET), polyethylene naphathalate (PEN), polyimides, polymeric hydrocarons, celluloses, plastic, polycarbonate and polystyrene, for example, can be used as the cathode polymer layer 50.

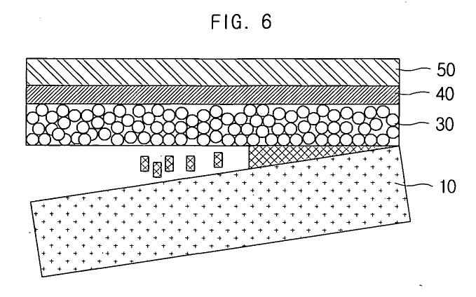

Next, as illustrated in FIG. 6, the carrier 10 is separated by removing the separation layer 20 (S500). Here, The method of removing the separation layer 20 can be varied in accordance with what material the separation layer 20 is made of, and in the case of the present embodiment, i.e. the separation layer 20 is made of ZnO, a corresponding method will be described below in order to remove the separation layer 20. The ZnO can be decomposed by sonicating in a subacidic bath, thereby removing the separation layer 20. In other words, the carrier 10 coupled to the electrode through the separation layer 20 is separated from the electrode, and thus the carrier 10 can be easily removed without physically or chemically harming the electrode.

Next, photosensitive dye is absorbed into the dye-absorption layer 30 (S600). As described above, the dye-absorption layer 30 is made of nano-crystal oxide, and thus the dye can be absorbed into the surface of the nano-crystal oxide. The photosensitive dye functions to separate electric charges and is very sensitive to light. Ruthenium-based organic metallic compounds, organic compounds and quantum-dot inorganic compounds, such as InP and CdSe, are some examples of the photosensitive dye, and a dye molecule generates an electron hole when receiving light.

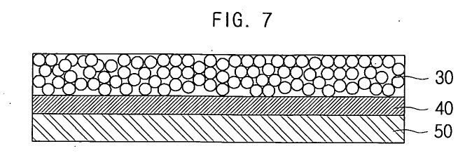

Illustrated in FIG. 7 is an electrode formed through the described process above, and the electrode having the dye-absorption layer formed thereon functions as a cathode in a dye-sensitized solar cell. In accordance with another embodiment of the present invention, a dye-sensitized solar cell can be manufactured by injecting an electrolyte between a cathode, manufactured in accordance with the flowchart in FIG. 1, and an anode, having a conductive substance layer formed thereon. The dye-sensitized solar cell described above is excellent in term of solar conversion efficiency and can be flexible, so that it can be used in several applications.

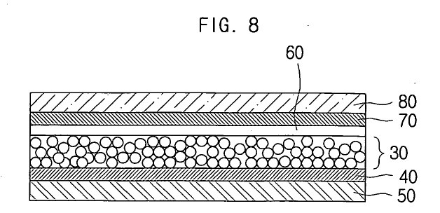

FIG. 8 is a cross sectional view illustrating a flexible dye-sensitized solar cell in accordance with another embodiment of the present invention. Illustrated in FIG. 8 are a dye-absorption layer 30, a carbon-nanotube layer 40, a cathode polymer layer 50, an electrolyte layer 60, a conductive substance layer 70 and an anode polymer layer 80.

The dye-absorption layer 30, absorbing photosensitive dye into itself, absorbs solar energy and converts it into electric energy by activating electrons. Nano-crystal oxide having a wider energy band gap can be used to form the dye-absorption layer 30, and TiO₂ is more commonly used as the nano-crystal oxide. Since the dye-absorption layer 30 is described above, a detailed description will be omitted.

The carbon-nanotube layer 40 can be formed on one surface of the dye-absorption layer 30 and made of a conductive polymer filled with carbon-nanotubes. A carbon-nanotubes (CNT), a new material, is basically a long hollow cylinder of graphite sheets with a nanostructure where 6 carbon atoms are arranged in a hexagonal lattice. A diameter of the long hollow cylinder is typically in a range of a few nanometers to a few ten nanometers, and the electrical conductivity of carbon-nanotubes is similar to that of copper. The carbon-nanotube is the greatest material, like a diamond, on earth in terms of thermal conductivity, and its strength is 100 times greater than a metal such as steel. A carbon fiber breaks when only 1% of its components deforms, but the carbon-nanotube can undergo a deformation up to a limit where 15% of its components deforms.

The carbon-nanotube layer 40 filled with a small amount of carbon-nanotubes can allow a ray of light to shin through it and sustain its form without breaking when repeatedly folded. The carbon-nanotube layer 40 can provide the required electrical conductivity with a small amount of carbon-nanotubes, collecting electrons excited from the dye-absorption layer 30.

The electrolyte layer 60 functions to provide a neighboring electron to fill a place where an electron has slipped away from the place and is composed of an redox couple, like I⁻/I₃⁻. If an electrolyte is a liquid, an redox ion couple can move freely in the electrolyte so that a dye can renew itself, improving the efficiency. However, if the bonding of electrodes is not strong enough, the electrolyte may leak. If a polymer is used as the electrolyte, it can be prevented from leaking. However, the movement of the redox couple can be slow down, reducing the efficiency. In the present embodiment, the two types of electrolytes described above can be applied to the electrolyte layer 60.

The conductive substance layer 70 functions as an anode. The conductive substance layer 70 is a thin film formed on an anode polymer layer 80, which allow electricity or heat to go through, by sputtering platinum, palladium, argentum (Ag) and aurum (Au), which are excellent in catalysis.

The carbon-nanotube layer 40 and the cathode polymer layer 50 or the anode polymer layer 80, which is adjacent to the conductive substance layer 70, are layers providing a base for an electrode, and they can be made of a material that allows a ray of light to shin through it, be flexible and have electrical conductivity. Here, some examples for the material are listed: polyethylene terephthalate (PET); polyethylene naphathalate (PEN); polyimides; polymeric hydrocarons; celluloses; plastic; polycarbonate; and polystyrene.

The operating process of a dye-sensitized solar cell manufactured through the above process has shown that a dye molecule coupled to the dye-absorption layer 30 creates an electron hole when receiving a ray of light and an electron is injected into a conduction band of the dye-absorption layer 30 and transmitted to the carbon-nanotube layer 40 through an interface of nanoparticles, creating a current of a solar cell. A hole created in the dye molecule can be fill with an electron received through an oxidation-reduction reaction with an electrolyte.

In accordance with the embodiments of the present invention as set forth above, although the high temperature annealing process associated with the dye-sensitized solar cell is required, a flexible cathode transparent electrode can be manufactured by using the carbon nanotube, because the cathode can be manufactured by using the carbon nanotube and a flexible transparent board is used.

While the spirit of the invention has been described in detail with reference to particular embodiments, the embodiments are for illustrative purposes only and shall not limit the invention. It is to be appreciated that those skilled in the art can change or modify the embodiments without departing from the scope and spirit of the invention. As such, many embodiments other than those set forth above can be found in the appended claims.

What is claimed is:

1. A method of manufacturing a flexible dye-sensitized solar cell, the method comprising:
forming a separation layer on a carrier;
forming a dye-absorption layer on the separation layer;
forming a carbon-nanotube layer on the dye-absorption layer;
forming a cathode polymer layer on the carbon-nanotube layer, the cathode polymer layer being flexible; and
separating the carrier by removing the separation layer.

2. The method of claim 1, wherein the carrier is selected from a group consisting of glass, metal and silicone.

3. The method of claim 1, wherein the separation layer comprises ZnO.

4. The method of claim 3, wherein the separating of the carrier comprises removing the separation layer by sonicating ZnO in a subacidic environment.

5. The method of claim 1, wherein the forming of the dye-absorption layer comprises:
coating nano-crystal oxide; and
annealing the nano-crystal oxide.

6. The method of claim 5, wherein the nano-crystal oxide comprises TiO₂, ZnO, Nb₂O₅, WO₃, SnO₂ and MgO.

7. The method of claim 1, wherein the cathode polymer layer is made of a material including at least one selected from a group consisting of polyethylene terephthalate (PET), polyethylene naphathalate (PEN), polyimides, polymeric hydrocarons, celluloses, plastic, polycarbonate and polystyrene.

8. The method of claim 1, further comprising absorbing photosensitive dye into the dye-absorption layer.

9. An electrode of a flexible dye-sensitized solar cell, the electrode comprising:
a cathode polymer layer, the cathode polymer layer being flexible;
a carbon-nanotube layer formed on one surface of the cathode polymer layer; and
a dye-absorption layer formed on the carbon-nanotube layer.

10. The electrode of claim 9, wherein the cathode polymer layer is made of a material including at least one selected from a group consisting of polyethylene terephthalate (PET), polyethylene naphathalate (PEN), polyimides, polymeric hydrocarons, celluloses, plastic, polycarbonate and polystyrene.

11. The electrode of claim 9, wherein the dye-absorption layer is made of a material including one or more selected from a group consisting of TiO₂, ZnO, Nb₂O₅, WO₃, SnO₂ and MgO.

12. The electrode of claim 9, wherein photosensitive dye is absorbed into the dye-absorption layer.

13. A flexible dye-sensitized solar cell comprising:
a cathode, comprising: a cathode polymer layer, the cathode polymer layer being flexible; a carbon-nanotube layer formed on one surface of the cathode polymer layer; and a dye-absorption layer formed on the carbon-nanotube layer;
an anode, a conductive substance layer formed on the anode; and
an electrolyte being interposed between the cathode and the anode.

14. The flexible dye-sensitized solar cell of claim 13, wherein the cathode polymer layer is made of a material including at least one selected from a group consisting of polyethylene terephthalate (PET), polyethylene naphathalate (PEN), polyimides, polymeric hydrocarons, celluloses, plastic, polycarbonate and polystyrene.

15. The flexible dye-sensitized solar cell of claim 13, wherein the dye-absorption layer is made of a material including one or more selected from a group consisting of TiO₂, ZnO, Nb₂O₅, WO₃, SnO₂ and MgO.

16. The flexible dye-sensitized solar cell of claim 13, wherein photosensitive dye is absorbed into the dye-absorption layer.
